(19) United States
(12) Patent Application Publication
(10) Pub. No.: US 2020/0234961 A1
(43) Pub. Date: Jul. 23, 2020

(54) SUBSTRATE PROCESSING METHOD

(71) Applicant: Tokyo Electron Limited, Tokyo (JP)

(72) Inventors: Takeshi TAMURA, Koshi-shi, Kumamoto (JP); Munehisa KODAMA, Koshi-shi, Kumamoto (JP)

(21) Appl. No.: 16/637,314

(22) PCT Filed: Aug. 2, 2018
(86) PCT No.: PCT/JP2018/028975

§ 371 Date: Feb. 7, 2020

(30) Foreign Application Priority Data
Aug. 10, 2017 (JP) 2017-155478

(51) Int. Cl. H01L 21/304; B65G 49/07; H01L 21/677; H01L 21/683; H01L 21/78

(52) U.S. Cl. CPC H01L 21/304; B65G 49/07; H01L 21/78; H01L 21/6836; H01L 21/67706

(57) ABSTRACT

A substrate processing method includes processing a substrate, which has a first main surface to which a protection tape is attached, from a side of a second main surface thereof, which is opposite from the first main surface; and transferring the substrate in a state that an electrostatic supporter configured to be attracted by an electrostatic attraction force is connected to the substrate after being processed in the processing of the substrate. Since the substrate after being processed is transferred in the state that the electrostatic supporter is connected thereto, weakness of the substrate can be supported by the electrostatic supporter, so that deformation or damage of the substrate during the transfer thereof can be suppressed.

### TECHNICAL FIELD

The various aspects and embodiments described herein pertain generally to a substrate processing method.

### BACKGROUND

Recently, to meet a demand for reducing a size and a weight of a semiconductor device, a substrate such as a semiconductor wafer is thinned by grinding, after forming an element, a circuit, a terminal or the like on a first main surface of the substrate, a second main surface of the substrate opposite from the first main surface. When the substrate is thinned, the first main surface of the substrate is protected by a protection tape (see, for example, Patent Document 1). After or before the substrate is thinned, dicing of the substrate is performed.

### PRIOR ART DOCUMENT

Patent Document 1: Japanese Patent Laid-open Publication No. 2011-091240

### DISCLOSURE OF THE INVENTION

### Problems to be Solved by the Invention

In a manufacturing process for the semiconductor device, the substrate needs to be transferred between units configured to perform individual processes. Particularly, since the substrate after being subjected to a processing such as thinning or dicing is weak, the substrate may be damaged during the transfer thereof. Though the protection tape is attached to the substrate as mentioned above, strength of the protection tape is low so it is difficult to suppress the damage of the substrate.

In view of foregoing, exemplary embodiments provide a substrate processing method capable of improving transfer strength of the substrate in the manufacturing process for the semiconductor device.

### Means for Solving the Problems

In one exemplary embodiment, a substrate processing method includes processing a substrate, which has a first main surface to which a protection tape is attached, from a side of a second main surface thereof, which is opposite from the first main surface; and transferring the substrate in a state that an electrostatic supporter configured to be attracted by an electrostatic attraction force is connected to the substrate after being processed in the processing of the substrate.

### Effect of the Invention

According to the exemplary embodiment, it is possible to provide a substrate processing method capable of improving transfer strength of a substrate in a manufacturing process for a semiconductor device.

### BRIEF DESCRIPTION OF THE DRAWINGS

FIG. 1 is a plan view illustrating a substrate processing system according to an exemplary embodiment.

FIG. 2 is a perspective view illustrating a substrate after being processed by the substrate processing system.

FIG. 3 is a diagram illustrating a dicing unit.

FIG. 4 is a diagram illustrating a state of a substrate and an electrostatic supporter in a supporter connecting unit.

FIG. 5 is a diagram illustrating a state of the substrate and the electrostatic supporter in a supporter separating unit.

FIG. 6 is a diagram illustrating a rough grinding unit of a thinning unit.

FIG. 7 is a diagram of a state of the substrate and the electrostatic supporter in a supporter connecting unit.

FIG. 8 is a diagram illustrating an ultraviolet irradiating unit.

FIG. 9 is a diagram illustrating a state of the substrate and the electrostatic supporter in a supporter separating unit.

FIG. 10 is a diagram illustrating a mounting unit.

FIG. 11 is a diagram illustrating a state of the substrate and a protection tape in a protection tape peeling unit.

FIG. 12 is a flowchart of a substrate processing method according to the exemplary embodiment.

### DETAILED DESCRIPTION

Hereinafter, exemplary embodiments of the present disclosure will be described with reference to the accompanying drawings. To ease understanding of the present disclosure, same or corresponding parts will be assigned same reference numerals in the various drawings, and redundant description may be omitted. In the following description, the X direction, the Y direction and the Z direction are orthogonal to each other, and the X and Y directions are horizontal directions whereas the Z direction is a vertical direction. A rotational direction around a vertical axis is referred to as the θ direction.

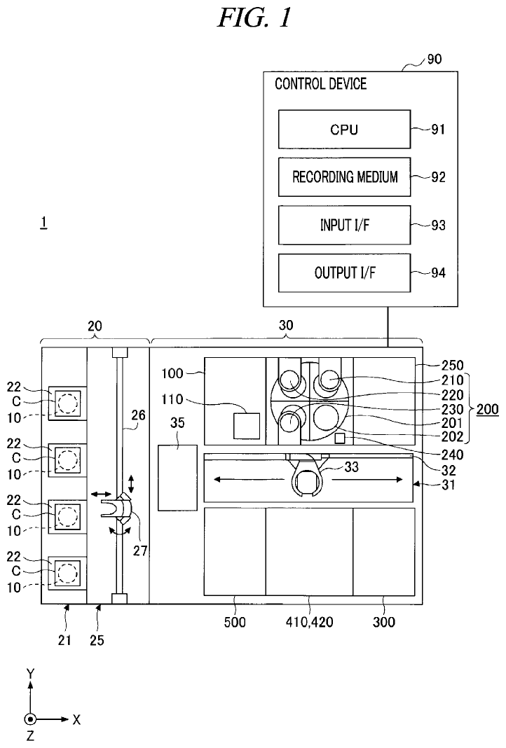

FIG. 1 is a plan view illustrating a substrate processing system 1 according to an exemplary embodiment. The substrate processing system 1 is configured to perform dicing of a substrate 10, thinning of the substrate 10, mounting of the substrate 10, attachment of a DAF to the substrate 10, and so forth. The substrate processing system 1 is equipped with a carry-in/out station 20, a processing station 30 and a control device 90.

Cassettes C are carried into/from the carry-in/out station 20 from/to the outside. Each cassette C accommodates therein a multiple number of substrates 10 while maintaining a regular distance between the substrates 10 in the Z direction. The carry-in/out station 20 is equipped with a placing table 21 and a transfer region 25.

The placing table 21 is equipped with multiple placing plates 22. The multiple placing plates 22 are arranged in a row in the Y direction. The cassettes C are placed on the placing plates 22. A cassette C on one placing plate 22 may accommodate therein substrates 10 before being processed, and a cassette C on another placing plate 22 may accommodate therein substrates 10 after being processed.

The transfer region 25 is disposed adjacent to the placing table 21 in the X direction. A transfer path 26 extending in the Y direction and a transfer device 27 configured to be movable along the transfer path 26 are provided in the transfer region 25. The transfer device 27 may be configured to be movable in the X direction, the Z direction and the θ direction as well as in the Y direction. The transfer device 27 transfers the substrates 10 between the cassette C placed on the placing plate 22 and a transition unit 35 of the processing station 30.

The processing station 30 is provided with a transfer region 31, the transition unit 35 and various kinds of processing units to be described later. Further, the layout and the number of the processing units are not limited to the example shown in FIG. 1 and can be selected as required. Further, the multiple processing units may be arranged while being dispersed or combined in arbitrary units.

The transfer region 31 is provided opposite from the transfer region 25 in the X direction with respect to the transition unit 35. The transition unit 35 and the various kinds of processing units are disposed adjacent to the transfer region 31 to surround the transfer region 31.

A transfer path 32 extending in the X direction and a transfer device 33 configured to be movable along the transfer path 32 are provided in the transfer region 31. The transfer device 33 may be configured to be movable in the Y direction, the Z direction and the θ direction as well as in the X direction. The transfer device 33 transfers the substrates 10 between the processing units adjacent to the transfer region 31.

The control device 90 is implemented by, for example, a computer and includes, as illustrated in FIG. 1, a CPU (Central Processing Unit) 91, a recording medium 92 such as a memory, an input interface 93 and an output interface 94. The control device 90 performs various kinds of controls by allowing the CPU 91 to execute a program stored in the recording medium 92. Further, the control device 90 receives a signal from an outside through the input interface 93 and transmits a signal to the outside through the output interface 94.

The program of the control device 90 is stored in information recording medium and installed from the information recording medium. The information recording medium may be, by way of non-limiting example, a hard disk (HD), a flexible disk (FD), a compact disk (CD), a magnet optical disk (MO), a memory card, or the like. Further, the program may be installed by being downloaded from a server through Internet.

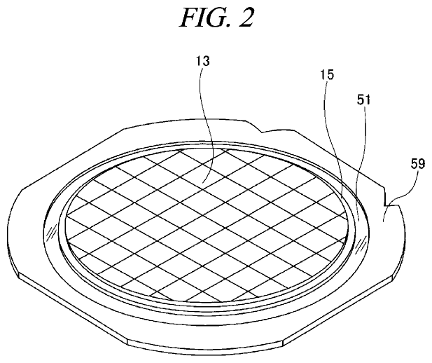

FIG. 2 is a perspective view illustrating a substrate 10 after being processed by the substrate processing system 1. The substrate 10 is mounted to a frame 59 with an adhesive tape 51 therebetween after being subjected to processings such as dicing, thinning and attachment of a DAF (Die Attach Film) 15.

The adhesive tape 51 includes a sheet member and an adhesive coated on a surface of the sheet member. The adhesive tape 51 is fixed to the frame 59 to cover an opening of the frame 59 having a ring shape and is attached to the substrate 10 in the opening of the frame 59. Accordingly, it is possible to transfer the substrate 10 by holding the frame 59, so that handling of the substrate 10 can be improved.

The DAF 15 may be provided between the adhesive tape 51 and the substrate 10, as depicted in FIG. 2. The DAF 15 is an adhesive sheet for die bonding. The DAF 15 is used to bond chips stacked on top of each other, bond a chip and a base, and so forth. The DAF 15 may have conductivity or insulation property.

The DAF 15 is formed to be smaller than the opening of the frame 59, and is disposed at an inner side of the frame 59. The DAF 15 covers an entire second main surface 12 of the substrate 10. Further, if stacking of chips 13 is not performed, the DAF 15 is not necessary. In such a case, the substrate 10 may be fixed to the frame 59 with only the adhesive tape 51 therebetween.

Hereinafter, a dicing unit 100, a supporter connecting unit 110, a supporter separating unit 240, a thinning unit 200, a supporter connecting unit 250, a ultraviolet irradiating unit 300, a supporter separating unit 410, a mounting unit 420, a protection tape peeling unit 500 disposed in the processing station 30 will be described in this sequence.

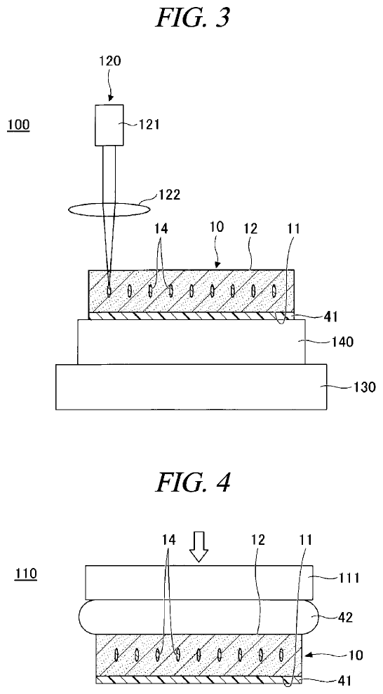

FIG. 3 is a diagram illustrating the dicing unit 100. The dicing unit 100 is configured to perform dicing of the substrate 10. Here, the dicing of the substrate 10 implies a processing of dividing the substrate 10 into the multiple chips 13. Particularly, in the present exemplary embodiment, stealth dicing (SD) of forming a modified layer 14 as a point of cutting within the substrate 10 by using a laser beam is performed, as illustrated in FIG. 3.

Further, the substrate 10 before being processed by the substrate processing system 1 may be, by way of non-limiting example, a semiconductor substrate such as a silicon wafer, a compound semiconductor wafer, or a sapphire substrate. A first main surface 11 of the substrate 10 before being processed is divided into multiple streets formed in a lattice shape, and a device layer including an element, a circuit, a terminal and so forth are previously formed in each divided region. Further, a protection tape 41 is attached on the first main surface 11 of the substrate 10 before being processed. The protection tape 41 protects the first main surface 11 of the substrate 10, thus protecting the element, the circuit, the terminal and so forth which are previously formed on the first main surface 11.

The protection tape 41 includes a sheet member and an adhesive coated on a surface of the sheet member. The adhesive may be hardened if an ultraviolet ray is irradiated thereto, so that adhesive strength thereof may be reduced. After the adhesive strength is weakened, the protection tape 41 can be simply peeled off the substrate 10 through a peeling operation. The protection tape 41 is attached to the substrate 10 to cover, for example, the entire first main surface 11 of the substrate 10. Further, besides the irradiation of the ultraviolet ray, a method using heat or laser may be applied as a way to harden the protection tape 41.

In the present exemplary embodiment, the substrate 10 is carried to the substrate processing system 1 with the protection tape 41 attached thereto. However, the protection tape 41 may be attached to the substrate 10 within the substrate processing system 1. That is, the substrate processing system 1 may be equipped with a processor configured to attach the protection tape 41 to the substrate 10.

The dicing unit 100 includes, by way of example, a substrate holder 140, a substrate processor 120 and a moving mechanism 130.

The substrate holder 140 is configured to hold the substrate 10 with the protection tape 41 therebetween. The substrate 10 may be held horizontally. By way of example, the substrate 10 is held such that the first main surface 11 protected by the protection tape 41 faces downwards while the second main surface 12 faces upwards. The substrate holder 140 may be, for example a vacuum chuck.

The substrate processor 120 is configured to perform the dicing of the substrate 10 held by, for example, the substrate holder 140. The substrate processor 120 is equipped with, by way of example, a laser oscillator 121 and an optical system 122 configured to irradiate a laser beam from the laser oscillator 121 to the substrate 10. The optical system 122 is composed of, for example, a condensing lens configured to concentrate the laser beam from the laser oscillator 121 toward the substrate 10.

The moving mechanism 130 allows the substrate holder 140 and the substrate processor 120 to be moved relative to each other. For example, the moving mechanism 130 may be composed of a XYZθ stage configured to move the substrate holder 140 in the X direction, the Y direction, the Z direction and the θ direction.

The control device 90 controls the substrate processor 120 and the moving mechanism 130 to carry out the dicing of the substrate 10 along the streets by which the substrate 10 is divided into the multiple chips 13. In the present exemplary embodiment, the laser beam which is capable of penetrating the substrate 10 is used.

Further, though the dicing unit 100 is disposed in the processing station 30 of the substrate processing system 1 in the present exemplary embodiment, the dicing unit 100 may be disposed at an outside of the substrate processing system 1. In such a case, the substrate 10 is carried into the carry-in/out station 20 from the outside after being diced.

FIG. 4 is a diagram illustrating a state of the substrate 10 and an electrostatic supporter 42 in the supporter connecting unit 110. The supporter connecting unit 110 is configured to connect the electrostatic supporter 42 to the substrate 10 after being diced.

The electrostatic supporter 42 is a reinforcing member which is connected to the substrate 10 when the substrate 10 is transferred. This electrostatic supporter 42 serves to improve transfer strength of the substrate 10 while suppressing deformation of the substrate 10 during the transfer thereof. The electrostatic supporter 42 is capable of attracting the substrate 10 by using a Coulomb force which is generated between the substrate 10 and the electrostatic supporter 42 by a voltage applied thereto.

The supporter connecting unit 110 is equipped with a transfer device 111 configured to transfer the electrostatic supporter 42, and the electrostatic supporter 42 is allowed to approach the substrate 10 from above by the transfer device 111. The transfer device 111 has a power feed device configured to apply positive and negative voltages to, for example, a pair of internal electrodes of the electrostatic supporter 42, respectively. As a result of the application of the voltages, dielectric polarization occurs in a dielectric layer ranging from electrode surfaces to a supporter surface. Accordingly, an attraction force (Coulomb force) is generated between the electrostatic supporter 42 and the substrate 10, so that the electrostatic supporter 42 and the substrate 10 are attracted to each other. Since this Coulomb force remains even after the power feed from the supporter connecting unit 110 to the electrostatic supporter 42 is stopped, the substrate 10 can be attracted to the electrostatic supporter 42 continuously while the substrate 10 is being transferred from a block of the dicing unit 100 to a block of the thinning unit 200 by the transfer device 33.

Further, the electrostatic supporter 42 is not limited to the bipolar type of the present exemplary embodiment and may be a monopolar type. Moreover, the electrostatic supporter 42 may be configured to use a Johnsen-Rahbek force or a gradient force instead of using the Coulomb force as in the present exemplary embodiment. In the following, the Coulomb force, the Johnsen-Rahbek force and the gradient force may be referred to as “electrostatic attraction force” together.

The supporter connecting unit 110 may connect the electrostatic supporter 42 to the second main surface 12 of the substrate 10. As compared to the case where the electrostatic supporter 42 is connected to the first main surface 11 of the substrate 10 with the protection tape 41 therebetween, a distance between the electrostatic supporter 42 and the substrate 10 can be shortened, so that the electrostatic attraction force can be increased. Therefore, unintended separation between the electrostatic supporter 42 and the substrate 10 can be suppressed.

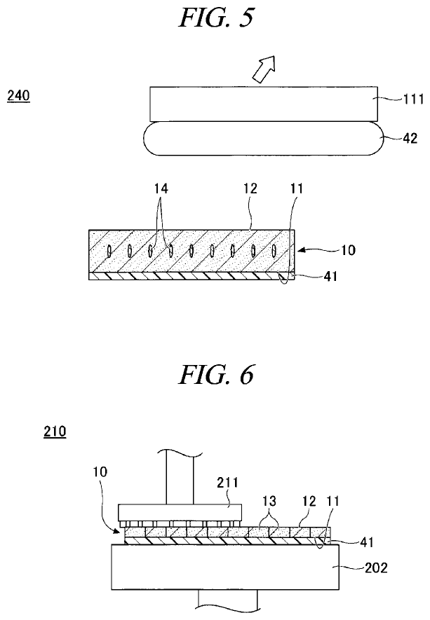

FIG. 5 is a diagram illustrating a state of the substrate 10 and the electrostatic supporter 42 in the supporter separating unit 240. The supporter separating unit 240 is provided in the block of the thinning unit 200. The supporter separating unit 240 is configured to separate the electrostatic supporter 42 from the substrate 10 which is transferred into the block of the thinning unit 200 from the block of the dicing unit 100 in the state that the electrostatic supporter 42 is connected thereto.

The supporter separating unit 240 is equipped with, for example, the same transfer device 111 as that of the supporter connecting unit 110, and the transfer device 111 has the power feed device configured to apply positive and negative voltages to the pair of internal electrodes of the electrostatic supporter 42, respectively. The supporter separating unit 240 removes the attraction force between the electrostatic supporter 42 and the substrate 10 by the application of the voltages from the power feed device, thus separating the electrostatic supporter 42 from the substrate 10. Accordingly, the second main surface 12 of the substrate 10 from which the electrostatic supporter 42 is separated can be processed by the thinning unit 200.

The thinning unit 200 (see FIG. 1) is configured to thin the substrate 10 by processing the second main surface 12 of the substrate 10 after being diced. The second main surface 12 is opposite from the first main surface 11 protected by the protection tape 41. In case that the point of cutting (modified layer 14) is formed by the dicing unit 100, a processing stress acts on the substrate 10 during the thinning, and a crack develops from the point of cutting in a plate thickness direction. As a result, the substrate 10 is divided into the multiple chips 13. By thinning the substrate 10 after being diced, the modified layer 14 can be removed.

The thinning unit 200 is equipped with, as illustrated in FIG. 1, for example, a rotary table 201, chuck tables 202 as substrate attracting units, a rough grinding unit 210, a fine grinding unit 220 and a damage layer removing unit 230.

The rotary table 201 is pivoted around a central line thereof. A plurality of (e.g., four in FIG. 1) chuck tables 202 are arranged around the central line of the rotary table 201 at a regular distance therebetween.

The chuck tables 202 are pivoted around the central line of the rotary table 201 along with the rotary table 201. The central line of the rotary table 201 is vertical. Whenever the rotary table 201 is rotated, the chuck tables 202 facing the rough grinding unit 210, the fine grinding unit 220 and the damage layer removing unit 230 are changed.

Each chuck table 202 attracts the substrate 10 with the protection tape 41 therebetween. The chuck table 202 is, for example, a vacuum chuck. The substrate 10 may be held horizontally. By way of example, the substrate 10 is held such that the first main surface 11 protected by the protection tape 41 faces downwards and the second main surface 12 of the substrate 10 faces upwards.

FIG. 6 is a diagram illustrating the rough grinding unit 210 of the thinning unit 200. The rough grinding unit 210 is configured to perform rough grinding of the substrate 10. The rough grinding unit 210 is equipped with, as depicted in FIG. 6, for example, a rotary whetstone 211. The rotary whetstone 211 is configured to be pivoted around a central line thereof and be moved down to process a top surface (that is, the second main surface 12) of the substrate 10 held by the chuck table 202. A grinding liquid is supplied onto the top surface of the substrate 10.

The fine grinding unit 220 is configured to perform fine grinding of the substrate 10.

The damage layer removing unit 230 is configured to remove a damage layer which is formed on the second main surface 12 of the substrate 10 by the grinding such as the rough grinding or the fine grinding.

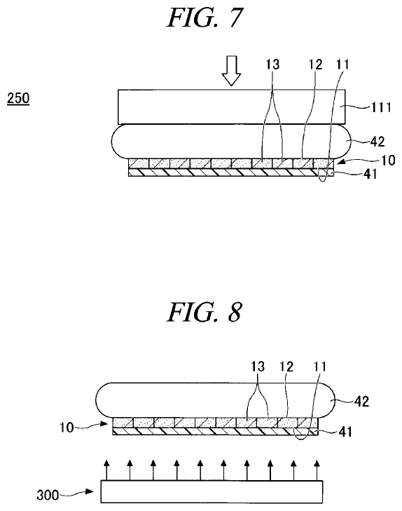

FIG. 7 is a diagram illustrating a state of the substrate 10 and the electrostatic supporter 42 in a supporter connecting unit 250. The supporter connecting unit 250 is configured to connect the electrostatic supporter 42 to the substrate 10 after being thinned.

The supporter connecting unit 250 is equipped with, for example, the same transfer device 111 as that of the supporter connecting unit 110, and the transfer device 111 has the power feed device configured to apply positive and negative voltages to the pair of internal electrodes of the electrostatic supporter 42, respectively. The supporter connecting unit 250 generates an attraction force between the electrostatic supporter 42 and the substrate 10 by the application of the voltages from the power feed device, thus allowing the substrate 10 to be attracted to the electrostatic supporter 42.

The supporter connecting unit 250 may connect the electrostatic supporter 42 to the second main surface 12 of the substrate 10. As compared to the case where the electrostatic supporter 42 is connected to the first main surface 11 of the substrate 10 with the protection tape 41 therebetween, the distance between the electrostatic supporter 42 and the substrate 10 can be shortened, so that the electrostatic attraction force can be increased. Therefore, the unintended separation between the electrostatic supporter 42 and the substrate 10 can be suppressed. Besides, an ultraviolet ray may be irradiated to the protection tape 41 attached to the first main surface 11 of the substrate 10 in the state that the electrostatic supporter 42 is connected to the second main surface 12 of the substrate 10.

FIG. 8 is a diagram illustrating the ultraviolet irradiating unit 300. The ultraviolet irradiating unit 300 is configured to irradiate the ultraviolet ray to the protection tape 41 which is attached to the substrate 10. The adhesive of the protection tape 41 can be hardened by the irradiation of the ultraviolet ray, and the adhesive strength of the protection tape 41 can be reduced. After the adhesive strength is weakened, the protection tape 41 can be simply peeled off the substrate 10 through a peeling operation.

A UV lamp or the like may be used as the ultraviolet irradiating unit 300. The irradiation of the ultraviolet ray by the ultraviolet irradiating unit 300 is performed when the adhesive strength of the protection tape 41 is high, and is performed before the peeling operation of the protection tape 41.

The ultraviolet irradiating unit 300 may be provided at an opposite side from the substrate 10 with respect to the protection tape 41. Accordingly, the ultraviolet ray can be directly irradiated to the protection tape 41 which is attached to the first main surface 11 of the substrate 10. Further, besides the irradiation of the ultraviolet ray, a method using heat or laser may be applied as a way to harden the protection tape 41.

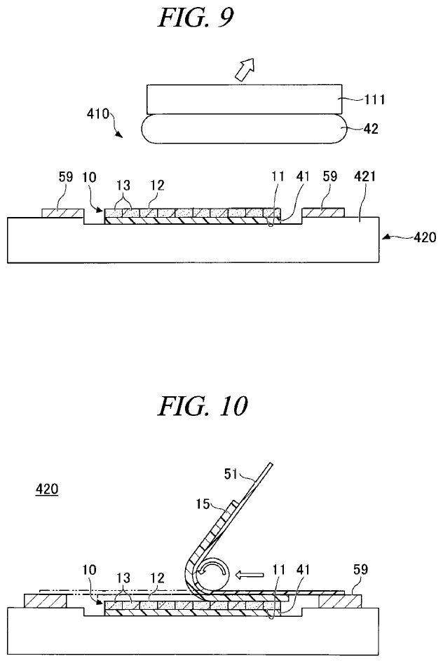

FIG. 9 is a diagram illustrating a state of the substrate 10 and the electrostatic supporter 42 in the supporter separating unit 410. The supporter separating unit 410 is provided in a block of the mounting unit 420. The supporter separating unit 410 is configured to separate the electrostatic supporter 42 from the substrate 10 which is transferred into the block of the mounting unit 420 from the block of the ultraviolet irradiating unit 300 in the state that the electrostatic supporter 42 is connected thereto.

The supporter separating unit 410 is equipped with, for example, the same transfer device 111 as that of the supporter separating unit 240, and the transfer device 111 has the power feed device configured to apply positive and negative voltages to the pair of internal electrodes of the electrostatic supporter 42, respectively. The supporter separating unit 410 removes the attraction force between the electrostatic supporter 42 and the substrate 10 by the application of the voltages from the power feed device, thus separating the electrostatic supporter 42 from the substrate 10. Accordingly, the adhesive tape 51 can be attached to the second main surface 12 of the substrate 10 from which the electrostatic supporter 42 is separated.

In the present exemplary embodiment, the supporter separating unit 410 is configured to separate the electrostatic supporter 42 from the substrate 10 after the frame 59 is mounted to surround the substrate 10. That is, the separation of the electrostatic supporter 42 is carried out after the substrate 10 is mounted at a preset position of the mounting unit 420. However, a timing for separating the electrostatic supporter 42 from the substrate 10 is not limited thereto as long as the electrostatic supporter 42 is separated at least before the adhesive tape 51 is attached to the second main surface 12 of the substrate 10 by the mounting unit 420.

FIG. 10 is a diagram illustrating the mounting unit 420. The mounting unit 420 is configured to mount the substrate 10 after being diced and thinned to the frame 59 from the second main surface 12 side with the adhesive tape 51 therebetween. The adhesive tape 51 is fixed to the frame 59 to cover the annular opening of the frame 59, as illustrated by a dashed double-dotted line in FIG. 10, and attached to the second main surface 12 of the substrate 10 in the opening of the frame 59.

In the mounting unit 420, the substrate 10 after being diced and thinned may be mounted to the frame 59 with only the adhesive tape 51 therebetween. In FIG. 10, however, the substrate 10 is mounted to the frame 59 with the adhesive tape 51 and the DAF 15, which are stacked on top of each other in advance, therebetween.

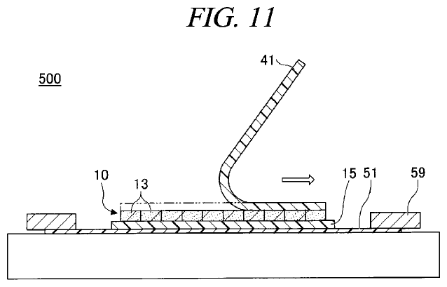

FIG. 11 is a diagram illustrating a state of the substrate 10 and the protection tape 41 in the protection tape peeling unit 500. The protection tape peeling unit 500 is configured to peel the protection tape 41 off the substrate 10 which is mounted to the frame 59 with the adhesive tape 51 therebetween by the mounting unit 420, as illustrated by a dashed double-dotted line in FIG. 11.

The protection tape peeling unit 500 peels the protection tape 41 off the substrate 10 while transforming the protection tape 41 from one end of the substrate 10 toward the other end thereof gradually.

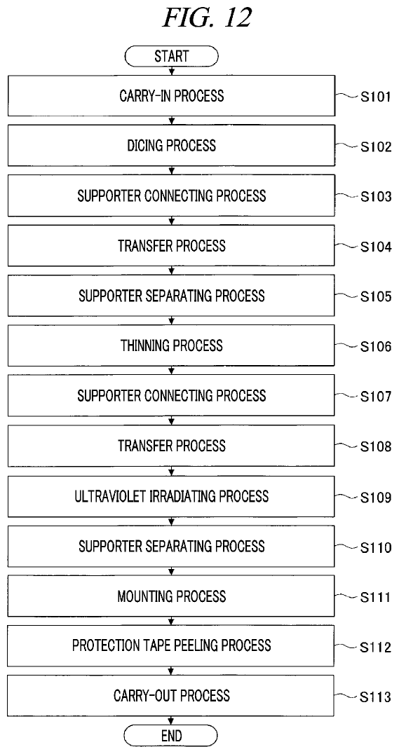

Now, a substrate processing method using the substrate processing system 1 having the above-described configuration will be discussed. FIG. 12 is a flowchart of the substrate processing method according to the exemplary embodiment.

As depicted in FIG. 12, the substrate processing method includes a carry-in process S101, a dicing process S102 (a processing process), a supporter connecting process S103 (an after-dicing supporter connecting process), a transfer process S104 (an after-dicing transfer process), a supporter separating process S105 (an after-dicing supporter separating process), a thinning process S106 (a processing process), a supporter connecting process S107 (an after-thinning supporter connecting process), a transfer process S108 (an after-thinning transfer process), an ultraviolet irradiating process S109, a supporter separating process S110 (an after-thinning supporter separating process), a mounting process S111, a protection tape peeling process S112 and a carry-out process S113. These processes are performed under the control of the control device 90. Further, a sequence of these processes is not limited to an example shown in FIG. 12. For example, the dicing process S102 may be performed after the thinning process S106.

In the carry-in process S101, the transfer device 27 transfers the substrate 10 from the cassette C on the placing table 21 into the transition unit 35 of the processing station 30, and, then, the transfer device 33 transfers the substrate 10 from the transition unit 35 into the dicing unit 100.

In the dicing process S102, the dicing unit 100 performs the dicing of the substrate 10 along the streets by which the substrate 10 is divided into the multiple chips 13, as illustrated in FIG. 3.

In the supporter connecting process S103, the supporter connecting unit 110 connects the electrostatic supporter 42 to the second main surface 12 of the substrate 10 after being diced in the process S102, as shown in FIG. 4.

In the transfer process S104, the transfer device 33 attracts, via the electrostatic supporter 42, the substrate 10 to which the electrostatic supporter 42 is connected in the process S103 and transfers the substrate 10 from the block of the dicing unit 100 into the block of the thinning unit 200. Since the strength of the substrate 10 during the transfer thereof is enhanced due to the electrostatic supporter 42 connected to the substrate 10, it is possible to transfer the substrate 10 stably even by partial attraction, not by whole-surface attraction.

In the supporter separating process S105, as depicted in FIG. 5, the supporter separating unit 240 separates the electrostatic supporter 42 from the substrate 10 which is transferred into the block of the thinning unit 200 from the block of the dicing unit 100 in the state that the electrostatic supporter 42 is connected thereto in the process S104.

In the thinning process S106, the thinning unit 200 thins the substrate 10 by processing the second main surface 12 of the substrate 10 opposite from the first main surface 11, as illustrated in FIG. 6. At this time, the first main surface 11 of the substrate 10 is protected by the protection tape 41.

In the supporter connecting process S107, as shown in FIG. 7, the supporter connecting unit 250 connects the electrostatic supporter 42 to the second main surface 12 of the substrate 10 which is thinned in the process S106. The supporter connecting unit 250 allows the electrostatic supporter 42 to be attracted to the second main surface 12 of the substrate 10 after the second main surface 12 ground by the thinning unit 200 is cleaned and dried.

In the transfer process S108, the transfer device 33 attracts, via the electrostatic supporter 42, the substrate 10 to which the electrostatic supporter 42 is connected in the process S107, and transfers the substrate 10 into the block of the ultraviolet irradiating unit 300 from the block of the supporter connecting unit 250.

In the ultraviolet irradiating process S109, the ultraviolet irradiating unit 300 irradiates the ultraviolet ray to the protection tape 41, as depicted in FIG. 8. The ultraviolet irradiating unit 300 is provided at the opposite side from the substrate 10 with respect to, for example, the protection tape 41, and, accordingly, the ultraviolet ray can be directly irradiated to the protection tape 41 which is attached to the first main surface 11 of the substrate 10. The adhesive of the protection tape 41 can be hardened by the irradiation of the ultraviolet ray, and the adhesive strength of the protection tape 41 can be weakened. Thus, the protection tape 41 can be easily peeled off the substrate 10 in the protection tape peeling process S112.

Though the ultraviolet irradiating process S109 may be performed after the mounting process S111, the ultraviolet irradiating process S109 is performed before the mounting process S111 in the present exemplary embodiment. Accordingly, degradation of the adhesive tape 51 by the irradiation of the ultraviolet ray can be suppressed. Further, besides the irradiation of the ultraviolet ray, a method using heat or laser may be applied as a way to harden the protection tape 41. Upon the completion of the ultraviolet irradiating process S109, the transfer device 33 transfers the substrate 10 from the block of the ultraviolet irradiating unit 300 into the block of the mounting unit 420.

In the supporter separating process S110, as depicted in FIG. 9, the supporter separating unit 410 separates the electrostatic supporter 42 from the substrate 10 which is transferred into the block of the mounting unit 420 from the block of the ultraviolet irradiating unit 300. In the present exemplary embodiment, the supporter separating unit 410 separates the electrostatic supporter 42 from the substrate 10 after the frame 59 is placed around the substrate 10, as will be described later with reference to FIG. 9. However, the timing for separating the electrostatic supporter 42 from the substrate 10 is not limited thereto as long as the electrostatic supporter 42 is separated at least before the adhesive tape 51 is attached to the substrate 10 and the frame 59 by the mounting unit 420.

In the mounting process S111, the mounting unit 420 mounts the substrate 10 after being diced and thinned to the frame 59 from the second main surface 12 side with the adhesive tape 51 therebetween, as shown in FIG. 10.

In the protection tape peeling process S112, as shown in FIG. 11, the protection tape peeling unit 500 peels the protection tape 41 off the substrate 10 which is mounted to the frame 59 with the adhesive tape 51 therebetween in the mounting process S111.

In the carry-out process S113, the transfer device 33 transfers the substrate 10 from the protection tape peeling unit 500 into the transition unit 35, and, then, the transfer device 27 transfers the substrate 10 from the transition unit 35 into the cassette Con the placing table 21. The transfer device 33 and the transfer device 27 transfer the substrate 10 by holding the frame 59. The cassette C is carried from the placing table 21 to the outside. The multiple chips 13 of the substrate 10 carried to the outside are picked up individually. In this way, the semiconductor devices including the chips 13 are manufactured.

Now, effects of the substrate processing method according to the present exemplary embodiment will be explained. The substrate processing method includes: the processing processes (the dicing process S102 and the thinning process S106) of processing the substrate 10 from the second main surface 12 side thereof opposite from the first main surface 11 to which the protection tape 41 is attached; and the transfer processes S104 and S108 of transferring the substrate 10 in the state that the electrostatic supporter 42 configured to be attracted by the electrostatic attraction force is connected to the substrate 10 processed in the processing processes.

If the substrate 10 after being processed is transferred by being directly attracted to the transfer device 33, the substrate 10 may be rolled up, deformed or damaged during the transfer of the substrate 10 because the substrate 10 is thin. In the present exemplary embodiment, however, since the substrate 10 is transferred in the state that the electrostatic supporter 42 is connected to the substrate 10 after being subjected to the processing such as the thinning or the dicing as described above, the weakness of the substrate 10 can be supported by the electrostatic supporter 42. Accordingly, the deformation or the damage of the substrate 10 during the transfer thereof can be suppressed. Thus, the substrate processing method according to the present exemplary embodiment is capable of improving the transfer strength of the substrate 10 in the manufacturing process of the semiconductor devices.

Conventionally, to stably transfer the substrate 10 after being subjected to the processing such as the thinning or the dicing, the transfer device 33 generally transfers the substrate 10 while attracting the whole surface of the substrate 10. In case of the whole-surface attraction, a complicated structure in which high accuracy is required in a positional relationship between the chuck of the transfer device 33 and the substrate 10 is needed. In the present exemplary embodiment, on the other hand, the substrate 10 is transferred in the transfer processes S104 and S108 by being attracted to the transfer device 33 via the electrostatic supporter 42 as in the above-described configuration. That is, the transfer device 33 does not attract the substrate 10 directly, and transfers the substrate 10 while attracting the electrostatic supporter 42. Since the electrostatic supporter 42 has higher strength than the substrate 10, the whole-surface attraction of the electrostatic supporter 42 by the transfer device 33 is not required, and it is possible to attract and transfer the substrate 10 stably even if a method such as partial attraction in which a required positioning accuracy is relatively low is used. Therefore, as compared to the conventional cases, the structure and the control for improving the transfer strength of the substrate 10 can be simply achieved.

Further, there is a method of performing a manufacture of a semiconductor device in a state that a support board is bonded to a substrate 10 as a processing target to enhance strength of the substrate 10 (see, for example, Japanese Patent Laid-open Publication No. 2014-110387, etc.). However, this method requires, after the completion of the processing, an operation of inserting a sharp member into a joint portion between the substrate 10 and the support board to separate the support board from the substrate 10 or an operation of cleaning a bonding surface of the substrate 10 which is bonded to the support board, and so forth. As a result, the number of processes required is increased and the method is complicated. In the present exemplary embodiment, however, since the electrostatic supporter 42 configured to be connected to the substrate 10 by using the electrostatic attraction force is used as the reinforcing member to enhancing the strength of the substrate 10, attachment and detachment between the substrate 10 and the electrostatic supporter 42 are carried out simply by the power feed to the electrostatic supporter 42. Thus, the complication of the processing can be suppressed.

Furthermore, the substrate processing method according to the present exemplary embodiment includes the thinning process S106 of thinning the substrate 10 by grinding the second main surface 12. Further, the substrate processing method according to the present exemplary embodiment also includes the supporter connecting process S107 of connecting the electrostatic supporter 42 to the second main surface 12 of the substrate 10 after being thinned in the thinning process S106; the transfer process S108 of transferring the substrate 10 by attracting the substrate 10 with the transfer device 33 via the electrostatic supporter 42 in the state that the electrostatic supporter 42 is connected to the substrate 10 in the supporter connecting process S107; the supporter separating process S110 of separating the electrostatic supporter 42 from the substrate 10 after the substrate 10 is transferred to a preset position (the mounting unit 420 in the present exemplary embodiment) in the transfer process S108.

In the supporter connecting process S107, the electrostatic supporter 42 is connected to the second main surface 12 of the substrate 10. Thus, as compared to the case where the electrostatic supporter 42 is connected to the first main surface 11 of the substrate 10 with the protection tape 41 therebetween, the distance between the electrostatic supporter 42 and the substrate 10 can be shortened, so that the electrostatic attraction force can be increased. Thus, the unintended separation between the electrostatic supporter 42 and the substrate 10 can be suppressed in the transfer process S108. Furthermore, by separating the electrostatic supporter 42 from the substrate 10 in the supporter separating process S110, the adhesive tape 51 can be attached, in the following mounting process S111, to the second main surface 12 of the substrate 10 from which the electrostatic supporter 42 is separated.

Further, the substrate processing method according to the present exemplary embodiment includes the dicing process S102 in which the dicing of the substrate 10 is performed from the second main surface side 12 thereof; the supporter connecting process S103 in which the electrostatic supporter 42 is connected to the second main surface 12 of the substrate 10 after being diced in the dicing process S102; the transfer process S104 in which the substrate 10 is transferred by being attracted to the transfer device 33 via the electrostatic supporter 42 in the state that the electrostatic supporter 42 is connected to the substrate 10 in the supporter connecting process S103; and the supporter separating process S105 in which the electrostatic supporter 42 is separated from the substrate 10 after the substrate 10 is transferred to a preset position (the thinning unit 200 in the present exemplary embodiment) in the transfer process S104.

In the supporter connecting process S103, the electrostatic supporter 42 is connected to the second main surface 12 of the substrate 10. Thus, as compared to the case where the electrostatic supporter 42 is connected to the first main surface 11 of the substrate 10 with the protection tape 41 therebetween, the distance between the electrostatic supporter 42 and the substrate 10 can be shortened, so that the electrostatic attraction force can be increased. Thus, the unintended separation between the electrostatic supporter 42 and the substrate 10 can be suppressed in the transfer process S104. Furthermore, by separating the electrostatic supporter 42 from the substrate 10 in the supporter separating process S105, the second main surface 12 of the substrate 10 from which the electrostatic supporter 42 is separated can be processed in the following thinning process S106.

Moreover, in the substrate processing method according to the present exemplary embodiment, the thinning of the substrate 10 is performed in the thinning process S106 after the dicing of the substrate 10 is performed in the dicing process S102. Accordingly, the modified layer 14 formed within the substrate 10 by the dicing can be completely removed by the thinning processing.

Further, in the present exemplary embodiment, both the method of connecting the electrostatic supporter 42 to the substrate 10 when transferring the substrate 10 from the block of the dicing unit 100 to the block of the thinning unit 200 as in the processes S103 to S105 and the method of connecting the electrostatic supporter 42 to the substrate 10 when transferring the substrate 10 from the block of the supporter connecting unit 250 to the mounting unit 420 via the block of the ultraviolet irradiating unit 300 as in the processes S107 to S110 are performed. However, any one of these methods may be performed. Furthermore, in case that the order of the dicing process S102 and the thinning process 106 is changed, the processes S107 to S110 are performed prior to the processes S103 to S105.

In addition, the substrate processing method according to the present exemplary embodiment includes the ultraviolet irradiating process S109 of irradiating, prior to the protection tape peeling process S112, the ultraviolet ray to the protection tape 41 attached to the first main surface 11 of the substrate 10. In the ultraviolet irradiating process S109, the substrate 10 is supported by the electrostatic supporter 42 which is connected to the second main surface 12 of the substrate 10.

Since the electrostatic supporter 42 is connected to the second main surface 12 opposite from the protection tape 41 with respect to the substrate, the ultraviolet ray can be easily irradiated to the protection tape 41 in the ultraviolet irradiating process S109. Therefore, in the following protection tape peeling process S112, the protection tape 41 can be easily peeled off the substrate 10. Further, since the electrostatic supporter 42 need not be separated in the ultraviolet irradiating process S109, the operation efficiency can be improved.

So far, the exemplary embodiments have been described. However, the present disclosure is not limited thereto. It should be understood that various appropriate design modifications made by those skilled in the art are included in the scope of the present disclosure as long as those modifications have the technical features of the present disclosure. The individual components described in the aforementioned exemplary embodiments and layouts, conditions and shapes thereof are not limited to the above-described examples and can be modified appropriately. The individual components of the above-described exemplary embodiments can be appropriately combined unless they are technically contradictory.

This patent application claims the benefit of priority to Japanese Patent Application No. 2017-155478 filed on Aug. 10, 2017 and incorporated herein by reference in its entirety.

### EXPLANATION OF CODES

10: Substrate
11: First main surface
12: Second main surface
41: Protection tape
42: Electrostatic supporter
51: Adhesive tape
59: Frame
S102: Dicing process (processing process)
S103: Supporter connecting process (after-dicing supporter connecting process)
S104: Transfer process (after-dicing transfer process)
S105: Supporter separating process (after-dicing supporter separating process)
S106: Thinning process (processing process)
S107: Supporter connecting process (after-thinning supporter connecting process)
S108: Transfer process (after-thinning transfer process)
S109: Ultraviolet irradiating process
S110: Supporter separating process (after-thinning supporter separating process)
S111: Mounting process
S112: Protection tape peeling process

We claim:

1. A substrate processing method, comprising:
processing a substrate, which has a first main surface to which a protection tape is attached, from a side of a second main surface thereof, which is opposite from the first main surface; and
transferring the substrate in a state that an electrostatic supporter configured to be attracted by an electrostatic attraction force is connected to the substrate after being processed in the processing of the substrate.

2. The substrate processing method of claim 1, further comprising:
thinning the substrate by grinding the second main surface;
connecting, after the thinning of the substrate, the electrostatic supporter to the second main surface of the substrate after being thinned in the thinning of the substrate;
transferring, after the thinning of the substrate, the substrate to which the electrostatic supporter is connected in the connecting, after the thinning of the substrate, of the electrostatic supporter, while attracting the substrate by a transfer device via the electrostatic supporter; and
separating, after the thinning of the substrate, the electrostatic supporter from the substrate after the substrate is transferred to a preset position in the transferring, after the thinning of the substrate, of the substrate,
wherein the processing of the substrate comprises the thinning of the substrate, and
the transferring of the substrate comprises the transferring, after the thinning of the substrate, of the substrate.

3. The substrate processing method of claim 1, further comprising:
dicing the substrate from the side of the second main surface;
connecting, after the dicing of the substrate, the electrostatic supporter to the second main surface of the substrate after being diced in the dicing of the substrate;
transferring, after the dicing of the substrate, the substrate to which the electrostatic supporter is connected in the connecting, after the dicing of the substrate, of the electrostatic supporter, while attracting the substrate by a transfer device via the electrostatic supporter; and
separating, after the dicing of the substrate, the electrostatic supporter from the substrate after the substrate is transferred to a preset position in the transferring, after the dicing of the substrate, of the substrate,
wherein the processing of the substrate comprises the dicing of the substrate, and
the transferring of the substrate comprises the transferring, after the dicing of the substrate, of the substrate.

4. The substrate processing method of claim 1, further comprising:
dicing the substrate from the side of the second main surface;
connecting, after the dicing of the substrate, the electrostatic supporter to the second main surface of the substrate after being diced in the dicing of the substrate;
transferring, after the dicing of the substrate, the substrate to which the electrostatic supporter is connected in the connecting, after the dicing of the substrate, of the electrostatic supporter, while attracting the substrate by a transfer device via the electrostatic supporter;
separating, after the dicing of the substrate, the electrostatic supporter from the substrate after the substrate is transferred to a preset position in the transferring, after the dicing of the substrate, of the substrate;
thinning the substrate by grinding the second main surface from which the electrostatic supporter is separated in the separating, after the dicing of the substrate, of the electrostatic supporter;
connecting, after the thinning of the substrate, the electrostatic supporter to the second main surface of the substrate after being thinned in the thinning of the substrate;
transferring, after the thinning of the substrate, the substrate to which the electrostatic supporter is connected in the connecting, after the thinning of the substrate, of the electrostatic supporter, while attracting the substrate by a transfer device via the electrostatic supporter; and
separating, after the thinning of the substrate, the electrostatic supporter from the substrate after the substrate is transferred to a preset position in the transferring, after the thinning of the substrate, of the substrate,
wherein the processing of the substrate comprises the dicing of the substrate and the thinning of the substrate, and
the transferring of the substrate comprises the transferring, after the dicing of the substrate, of the substrate and the transferring, after the thinning of the substrate, of the substrate.

5. The substrate processing method of claim 1, further comprising:
mounting the substrate to a frame from the side of the second main surface of the substrate with an adhesive tape therebetween; and
peeling the protection tape off the substrate which is mounted to the frame in the mounting of the substrate.

6. The substrate processing method of claim 5, further comprising:
irradiating, prior to the peeling of the protection tape, an ultraviolet ray to the protection tape which is attached to the first main surface of the substrate,
wherein, in the irradiating of the ultraviolet ray, the substrate is supported by the electrostatic supporter connected to the second main surface of the substrate.
